(19) United States
(12) Patent Application Publication
(10) Pub. No.: US 2014/0055969 A1
(43) Pub. Date: Feb. 27, 2014

(54) BOARD ASSEMBLIES WITH MINIMIZED WARPAGE AND SYSTEMS AND METHODS FOR MAKING THE SAME

(71) Applicants: Vu Thanh Vo, Salinas, CA (US); Dennis Pyper, San Jose, CA (US)

(72) Inventors: Vu Thanh Vo, Salinas, CA (US); Dennis Pyper, San Jose, CA (US)

(73) Assignee: APPLE INC., Cupertino, CA (US)

(21) Appl. No.: 13/590,706

(22) Filed: Aug. 21, 2012

(51) Int. Cl. H05K 7/06; H05K 13/04

(52) U.S. Cl. 361/783; 361/760; 403/373; 29/832

(57) ABSTRACT

Board assemblies with minimized warpage and systems and methods for making the same are disclosed. A board may be pre-conditioned by designing the board to mount components in selected areas of the board and by selectively copper flooding certain regions of the board. Pre-conditioning of the board may assist in preventing board warpage. A reflow fixture may fix a board during solder pasting and reflow processing thereof. After reflow, an underfill fixture may fix the board during underfill processing. Each of these fixtures may include respective clamp members that may hold various portions of the board to correct and/or prevent warpage of the board.

### FIELD OF THE INVENTION

This can relate to board assemblies having minimized warpage and systems and methods for making the same.

### BACKGROUND OF THE DISCLOSURE

Conventional board assemblies (e.g., solid state device (SSD) boards) are typically characterized by non-flat surfaces or warpage. Warpage may occur during various manufacturing stages of a board. For example, a board may undergo reflow processing after circuit components have been mounted thereon. As another example, a board may undergo underfill processing after reflow to provide structural integrity to various portions of the board. During each of these manufacturing stages, a board may experience high temperatures and other stressful conditions, which may cause the board to bend, become distorted, or otherwise warp. As a result, it may be difficult to insert or install the warped board into an electronic device.

### SUMMARY OF THE DISCLOSURE

Board assemblies having minimized warpage and systems and methods for making the same are provided.

In some embodiments, a board having a substantially flat surface throughout an entirety of the board is provided. The board includes a substrate having at least a top layer and a bottom layer. At least one of the top layer and the bottom layer includes a copper flooded region. The board also includes a plurality of components. The plurality of components includes a first set of components mounted on the top layer, and a second set of components mounted on the bottom layer. At least one of the copper flooded region, the first set of components, and the second set of components is selectively positioned on the board to prevent the board from warping beyond a predefined threshold degree of warpage.

In some embodiments, a board fixing apparatus for securing a plurality of boards each coupled via at least one tab that extends between two column members is provided. The apparatus includes a base unit including a plurality of regions. Each region is configured to hold a respective board of the plurality of boards. The apparatus also includes a first clamp including at least two notches. Each notch is configured to fix a respective column member of the two column members to the base unit to secure the plurality of boards to the base unit. The apparatus also includes a second clamp including at least one pin configured to press onto a portion of the at least one tab to further secure the plurality of boards to the base unit.

In some embodiments, a board fixing apparatus for securing a plurality of boards is provided. The apparatus includes a base part including a plurality of regions. Each region is configured to hold a respective one of the plurality of boards. The apparatus also includes a cover part including a plurality of notches. Each notch is configured to fix a portion of a respective one of the plurality of boards to the base part.

In some embodiments, a method for minimizing warpage of a board during manufacture is provided. The method includes situating a plurality of boards on a base unit of a board fixing apparatus. The plurality of boards are connected to one another via at least one tab that extends between two column members. The method also includes placing a first clamp of the board fixing apparatus onto the base unit to secure each of the two column members to the base unit, applying adhesive to select areas of each of the plurality of boards, and mounting respective components onto the applied adhesive of each of the plurality of boards. The method also includes disposing a pin clamp of the board fixing apparatus onto the base unit to secure a portion of the at least one tab to the base unit, and reflow processing each of the plurality of boards.

In some embodiments, a method for minimizing warpage of a board during manufacture is provided. The method includes situating a first side of each of a plurality of boards on a base part of a board fixing apparatus, placing a cover part of the board fixing apparatus onto the base part to substantially flatten each of the plurality of boards onto the base part, and underfill processing a second side of each of the plurality of boards. The method also includes removing the cover part from the base unit, positioning the second side of each of the plurality of boards onto the base part, and underfill processing the first side of each of the plurality of boards.

### BRIEF DESCRIPTION OF THE DRAWINGS

The above and other aspects and advantages of the invention will become more apparent upon consideration of the following detailed description, taken in conjunction with accompanying drawings, in which like reference characters refer to like parts throughout, and in which:

FIG. 1 shows a perspective view of a top side of a board, in accordance with at least one embodiment;

FIG. 2 shows a perspective view of a bottom side of the board of FIG. 1, after rotating the board in a direction P around a line X of FIG. 1, in accordance with at least one embodiment;

FIGS. 3-5 show various layers of a substrate of the board of FIG. 1, in accordance with at least one embodiment;

FIG. 6 shows a perspective view of a batch of board substrates, in accordance with at least one embodiment;

FIG. 7 shows a partially exploded view of a board fixture apparatus, in accordance with at least one embodiment;

FIG. 8 shows a perspective view of the board fixture apparatus of FIG. 7, in accordance with at least one embodiment;

FIG. 9 shows a top-down view of a bottom surface of the board fixture apparatus of FIG. 8, taken after rotating the board fixture apparatus of FIG. 8 in a direction R, in accordance with at least one embodiment;

FIG. 10 shows a side view of the board fixture apparatus of FIG. 8, taken along a line B of FIG. 8, in accordance with at least one embodiment;

FIG. 11 shows another side view of the board fixture apparatus of FIG. 8, taken along a line A of FIG. 8, in accordance with at least one embodiment;

FIG. 12 shows a partially exploded view of another board fixture apparatus, in accordance with at least one embodiment;

FIG. 13 shows a top view of the board fixture apparatus of FIG. 12, in accordance with at least one embodiment;

FIG. 14 shows a bottom view of the board fixture apparatus of FIG. 12, in accordance with at least one embodiment;

FIG. 15 shows a side view of the board fixture apparatus of FIG. 12, taken along a line W of FIG. 13, in accordance with at least one embodiment;

FIG. 16 shows another side view of the board fixture apparatus of FIG. 12, taken along a line U of FIG. 13, in accordance with at least one embodiment;

FIG. 17 shows an illustrative process for fixing a plurality of boards prior to and during reflow processing, in accordance with at least one embodiment;

FIG. 18 shows an illustrative process for fixing a plurality of boards for underfill processing, in accordance with at least one embodiment;

FIG. 19 is a schematic view of an illustrative electronic device including the board of FIG. 1, in accordance with at least one embodiment;

FIG. 20 shows a side view of a board having non-flat surfaces, in accordance with at least one embodiment; and

FIG. 21 shows a board having minimized warpage, in accordance with at least one embodiment.

### DETAILED DESCRIPTION OF THE DISCLOSURE

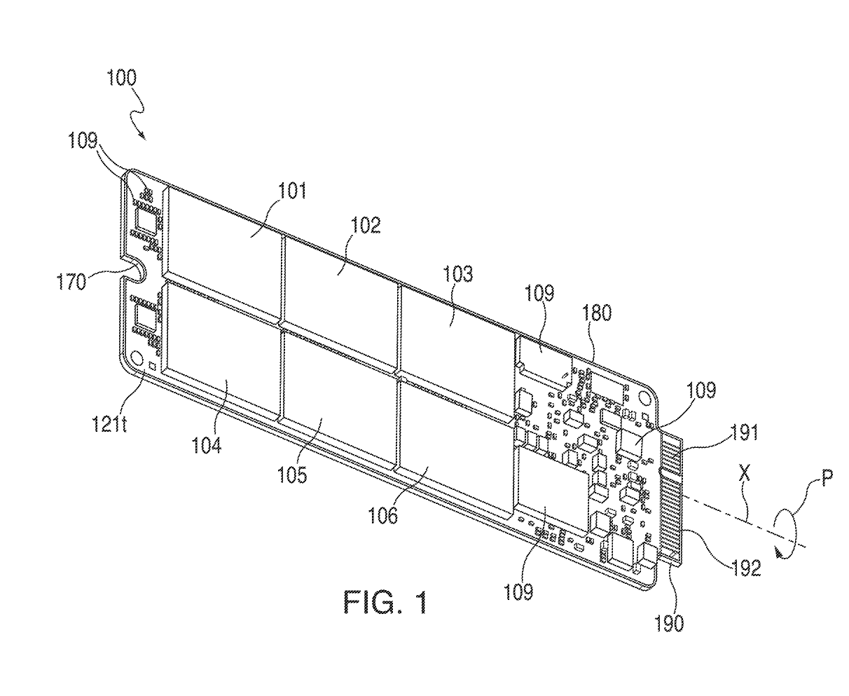

Board assemblies having minimized warpage and systems and methods for making the same are provided and described with reference to FIGS. 1-21.

FIG. 1 shows a perspective view of a top side board, in accordance with at least one embodiment. Board 100 may be included as part of an electronic device such as, for example, a portable media player, a smart phone, a laptop computer, or a tablet. Board 100 may be configured as an SSD board which typically includes one or more arrays of NAND-flash based memory (NAND chips). NAND chips may provide higher reliability and lower power consumption than hard disk drives.

Board 100 may include a substrate 180 having one or more components mounted thereon. Substrate 180 may be composed of silicon and/or any other suitable type of material. Substrate 180 may include a plurality of layers (described later) and may include a top surface 121t. Board 100 may include NAND chips 101, 102, 103, 104, 105, and 106 that may be mounted on top surface 121t in a predetermined manner (e.g., a first row of NAND chips 101, 102, and 103 may be mounted along one edge of substrate 180, and a second row of NAND chips 104, 105, and 106 may be mounted along an opposite edge of substrate 180 and adjacent the first row).

Board 100 may also include a plurality of circuit components 109 on top surface 121t. Each circuit component 109 may reside on top surface 121t in a predefined location (e.g., according to functional and physical (e.g., spacing) design requirements of board 100). Board 100 may include a larger number of circuit components 109 adjacent NAND chips 103 and 106, and a smaller number of circuit components 109 adjacent NAND chips 101 and 104. Circuit components 109 may include any circuitry component (e.g., resistors, capacitors, inductors, diodes, grounding contacts, leads, etc.) that may be required for operation of board 100.

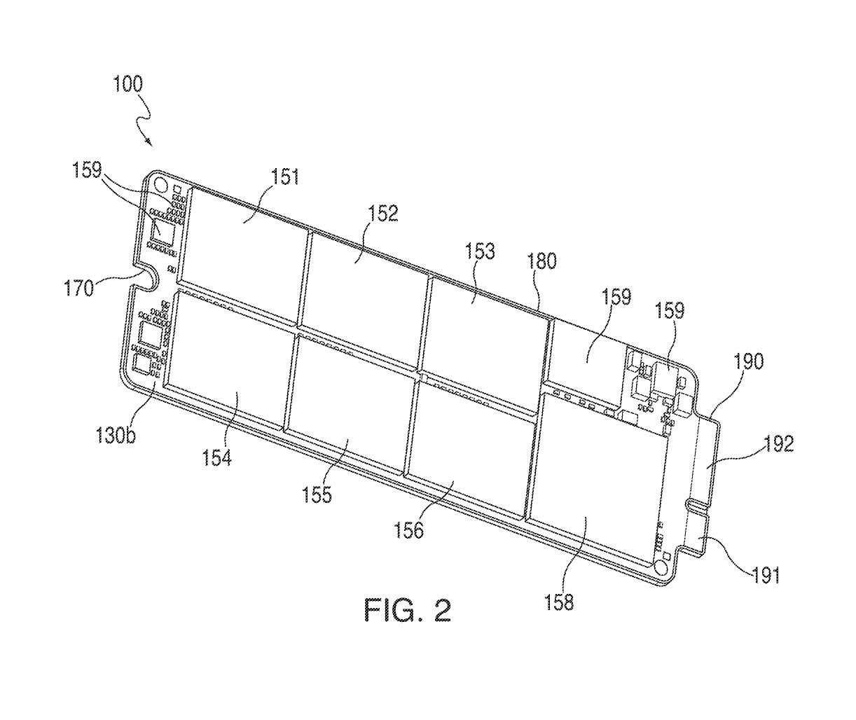

FIG. 2 shows a perspective view of a bottom side of the board of FIG. 1, after rotating the board in a direction P around a line X of FIG. 1, in accordance with at least one embodiment. As shown in FIG. 2, substrate 180 may include a bottom surface 130b.

Board 100 may include NAND chips 151, 152, 153, 154, 155, and 156 that may be mounted on bottom surface 130b in a predetermined manner (e.g., a first row of NAND chips 151, 152, and 153 may be mounted along one edge of substrate 180, and a second row of NAND chips 154, 155, and 156 may be mounted along an opposite edge of substrate 180 and adjacent the first row). The NAND chips on top surface 121t may be similar to the NAND chips on bottom surface 130.

Board 100 may also include a plurality of circuit components 159 on bottom surface 130b. Each circuit component 159 may reside on bottom surface 130b in a predefined location (e.g., according to functional and physical (e.g., spacing) design requirements of board 100). Board 100 may include a first set of circuit components 159 adjacent NAND chip 153, and a second set of circuit components 159 adjacent NAND chips 151 and 154. Circuit components 159 may be similar to circuit components 109.

In addition to circuit components 159, board 100 may also include a controller 158 on bottom surface 130b. Controller 158 may be coupled (e.g., via electrical contacts that may exist throughout various layers of substrate 180) to certain electrical contacts of each of NAND chips 101, 102, 103, 104, 105, 106, 151, 152, 153, 154, 155, and 156. Additionally, controller 158 may be electrically coupled to one or more of circuit components 109 and 159. Controller 158 may be configured to control the NAND chips and the circuit components (e.g., by writing data into the NAND chips, reading data stored in the NAND chips, etc.).

Board 100 may also include an interface 190 at an edge of board 100. Interface 190 may include an interface portion 191 and an interface portion 192. Electrical contacts of interface 190 may be coupled to controller 158 and any other component on board 100. In particular, each of interface portions 191 and interface portions 192 may include electrical contacts that may allow transfer of data to and/or from controller 158. Interface 190 may be used to couple board 100 with a corresponding interface of an electronic device.

Board 100 may also include a cutout 170 that may assist in aligning and positioning board 100 on one or more fixture apparatuses (described later).

Substrate 180 may be a printed circuit board (PCB). In some embodiments, substrate 180 may be a central or primary printed circuit board, and may also be known as a main circuit board, motherboard, mainboard, baseboard, system board, planar board, or logic board. Substrate 180 may provide one or more electrical attachment points to each one of the NAND chips, controller 158, and circuit components 109 and 159. Generally, most of the basic circuitry and components required for an electronic device to function may be onboard or coupled (e.g., via one or more cables, bond pads, leads, terminals, cables, wires, contact regions, etc.) to substrate 180.

Although not shown, substrate 180 may include solder and underfill material that may be applied between electrical contacts of top surface 121t and portions of the various components on top surface 121t. Similarly, substrate 180 may also include solder and underfill material that may be applied between electrical contacts of bottom surface 130b and portions of the various components on bottom surface 130b.

Board 100 may include solder to electrically and physically couple the NAND chips, controller 158 and circuit components 109 and 159 to substrate 180. Board 100 may also include underfill material on the solder, portions of substrate 180, and/or portions of the NAND chips, controller 158 and circuit components 109 and 159 to provide overall structural integrity. Underfill material may also prevent moisture and/or other environmental effects from damaging board 100 or interfering with the operation thereof.

A conventional board assembly, such as an SSD board, typically exhibits a non-flat disposition. This may be characterized by one or more of a crown, a bowed deflection, ridges, upturns, downturns, torsional rotation along a length of the board, and other artifacts of the board, and may thus disrupt the overall flatness of the board. For the sake of description, these characteristics are hereafter referred to as warping or warpage.

It is understood that obtaining a perfectly flat board may not be possible (e.g., a board may always be characterized by some sort of unevenness or warpage). However, it is desirable to manufacture boards that have minimized warpage. Thus, a board may be considered substantially flat throughout its entirety (and thus having minimized warpage) if any warpage of the board is less than a predefined threshold T. For example, a gradient or angle of bending of a board (with respect to flat surfaces of the board) may be used to define the board's degree of warpage. By measuring the gradient or angle of warpage and comparing it to the predefined threshold T, a board may be characterized as either substantially flat throughout its entirety (and thus having minimized warpage) or non-flat. The predefined threshold T may be set based on design requirements, such as space limitations of an electronic device that a board may be installable into. As an example, the predefined threshold T may be set to an angle anywhere from 0.1° to 5.0°.

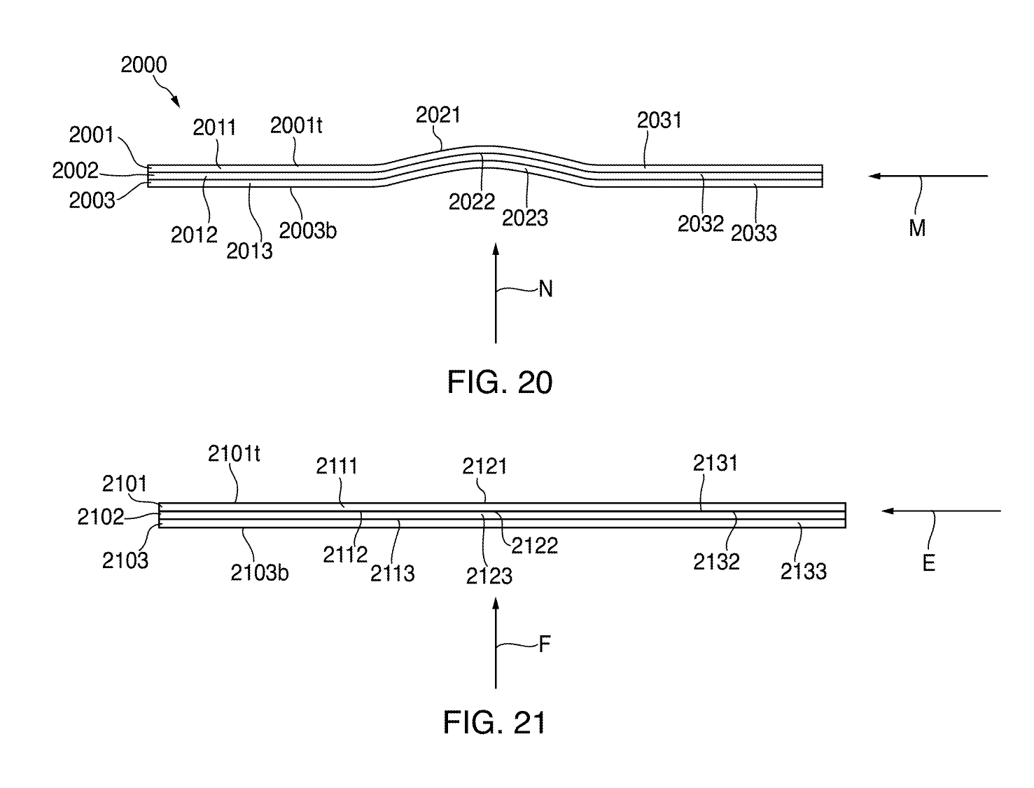

FIG. 20 shows a side view of a board having non-flat surfaces, in accordance with at least one embodiment. Board 2000 may include layers 2001, 2002, and 2003, and may include top surface 2001t and bottom surface 2003b. As shown in FIG. 20, board 2000 may include portions 2011, 2012, 2013, 2031, 2032, and 2033 that may be substantially flat (e.g., having a degree of warpage that is less than the predefined threshold T), but may also include portions 2021, 2022, and 2023 that may be non-flat (e.g., bent upward with respect to adjacent portions 2011, 2012, 2013, 2031, 2032, and 2033). That is, when viewing board 2000 in direction M, portion 2021 may appear to protrude from surface 2001t at an angle (e.g., an angle of protrusion that may be greater than the predefined threshold T). Similarly, when viewing board 2000 in a direction N, portion 2023 may appear as a dimple or dented into bottom surface 2003b.

FIG. 21 shows a board having minimized warpage, in accordance with at least one embodiment. Board 2100 may be similar to board 2000, may include layers 2101, 2102, and 2103, and may include top surface 2101t and bottom surface 2103b. As shown in FIG. 21, board 2100 may include portions 2111, 2112, 2113, 2131, 2132, and 2133 that may be substantially flat (e.g., having a degree of warpage that is less than the predefined threshold T), but may also include portions 2121, 2122, and 2123 that may slightly bend upward from surface 2101t. That is, when viewing board 2100 in direction E, portion 2121 may appear to slightly protrude from surface 2101t at an angle, but where the angle may be less than the predefined threshold T. Because the angle may be less than the predefined threshold T, board 2100 may be considered substantially flat throughout the entirety of board 2100 (and thus be minimally warped).

Warpage of a board can be caused by any number of factors. In particular, environmental conditions that a board may experience during various stages of its manufacture (e.g., component placement, application of solder, reflow processing, underfill processing, etc.) may each contribute to warpage of the board.

Board warpage occurs most often during reflow and underfill processing. During these processes, a board may experience large amounts of heat, which may cause portions of its substrate to bend one way or another. This bending may also be partly due to an imbalance of components on both sides of the board (e.g., the board may have too many components on one side, and too few components on another side). For example, components on one side of a board may be heavier and may cause the board to bend in one direction when subjected to heat during reflow or underfill.

A board that suffers from warpage may cause problems during its manufacture and installation (e.g., into an electronic device). For example, if a board suffers from warpage due to reflow processing, it may be difficult, or even impossible, to process the warped board with underfill. In some instances, even if the warped board may be successfully underfilled, it may be difficult to install the finished board into an electronic device (e.g., if the degree of warpage is so great that the board cannot fit into the confines of the electronic device).

To overcome the above mentioned challenges, board assemblies having minimized warpage and systems and methods for making the same are provided.

Conventionally manufactured boards may be examined during various stages of their manufacture to identify portions thereof that typically suffer from warpage and to determine the extent of such warpage. Based on this analysis, various techniques may be developed and employed to prevent warpage.

As described above, an imbalance of components on both sides of a board may cause the board to warp. Thus, “pre-conditioning” steps may be taken to help prevent a board from warping.

For example, selective placement and arrangement of the components on both sides of a board may help prevent warpage. As shown in FIGS. 1 and 2, board 100 may include the same number of NAND chips on top surface 121t and bottom surface 130b. Board 100 may also include components 109 on top surface 121t and a balancing of components 159 on bottom surface 130. Selective placement of these components may provide a weighted balance on both sides of board 100, and may thus help prevent warpage.

Each board may also require a single controller 158. Because controller 158 may be larger than each of the NAND chips and may only reside on one of top surface 121t and bottom surface 130b, a further step may be taken to counter any weighting imbalances of board 100 that may be contributed by controller 158. In particular, controller 158 may reside on bottom surface 130b, causing an imbalance in board 100. Thus, further pre-conditioning of board may help compensate for the imbalance.

Conventional boards are also typically copper flooded during manufacture (e.g., to electrically couple portions of the board to a ground plane of the board, etc.). Because the addition of flooded copper may improve structural integrity of a board, instead of flooding the entirety of the board (as is common in for conventional boards), the board may be selectively copper flooded to balance out particular portions of the board that may tend to warp.

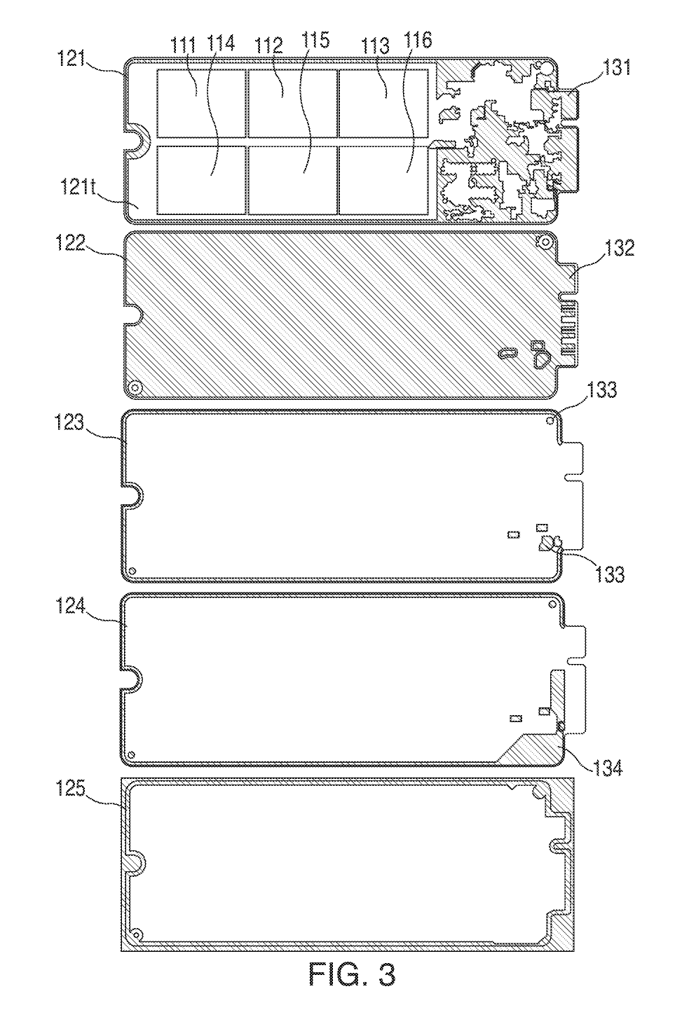

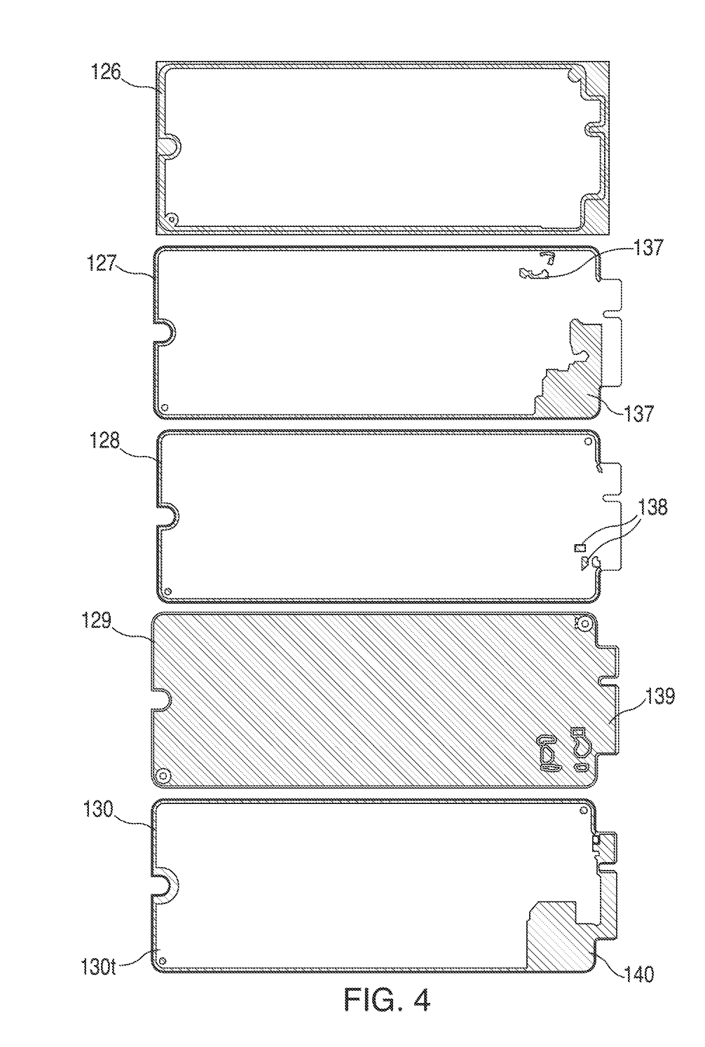

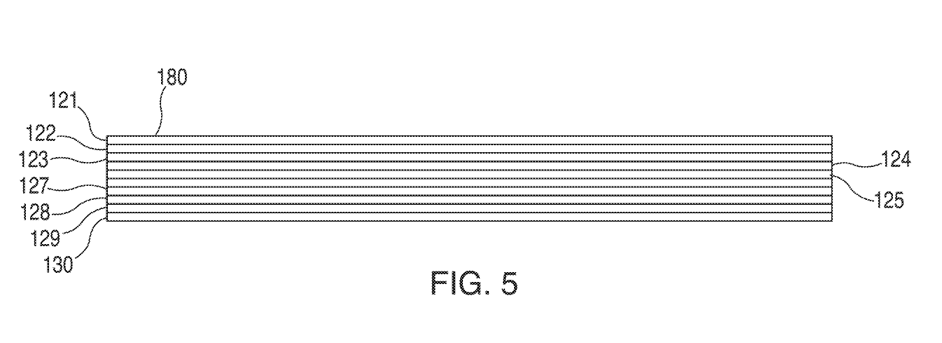

FIGS. 3-5 show various layers of a substrate of the board of FIG. 1, in accordance with at least one embodiment. As described above, substrate 180 of board 100 may include a plurality of layers. In particular, substrate 180 may include layers 121-130. Each layer may include a top surface and a bottom surface. When constructed, layer 121 may reside directly over layer 122, which in turn may reside directly over layer 123, and so on (as shown in FIG. 5). Layer 130 may be the bottom most layer of board 100. FIG. 4 shows top surface 130t of layer 130 (rather than bottom surface 130b).

To counter any warpage that may result from imbalance caused by controller 158 residing on bottom surface 130b, select areas around controller 158 may be copper flooded. For example, an entire region on which controller 158 resides (e.g., on bottom surface 130b) may be flooded with copper. In some embodiments, only regions of top surface 121t may be copper flooded. In other embodiments, only regions of bottom surface 130b may be copper flooded. In yet other embodiments, one or more of the layers of substrate 180 may be copper flooded. For example, as shown in FIGS. 3 and 4, layers 121-124 and 127-130 may include corresponding copper flooding 131-134 and 137-140.

Thus, certain pre-conditioning steps, such as designing substrate 180 to accommodate components on certain areas of substrate 180, and selectively copper flooding certain regions or layers of substrate 180, may assist in preventing warpage.

The pre-conditioning steps described above (e.g., selective component placement and selective copper flooding) may only help prevent warpage to a certain extent. For example, a board may also undergo reflow and underfill processing, which may each subject the board to large amounts of heat. In these environments, a board may still experience warpage even if it has been pre-conditioned. It should be appreciated, however, that although a pre-conditioned board may not be completely immune to warpage, its improved structural integrity and balance may still assist in minimizing warpage that may develop during reflow and underfill.

After a substrate (e.g., substrate 180) is designed and prepared, components may need to be mounted thereon. For example, substrate 180 may receive solder (e.g., via pasting or printing) on portions of top surface 121t and bottom surface 130b that may need to electrically couple with corresponding components. As shown in FIG. 3, substrate 180 may include placement areas 111-116 for mounting of NAND chips 101-106, and other areas for mounting of circuit components 109. Substrate 180 may receive solder paste on these specific areas.

The pasting of solder may require heat, which may affect the structural integrity of board 100, causing board 100 to warp. Thus, a mechanism (described below) for securing portions of substrate 180 during solder pasting may assist in preventing warpage.

After substrate 180 receives solder paste, it may undergo reflow processing. Reflow ensures that the solder paste thoroughly flows around all areas that require solder (e.g., the electrical contacts of the components). As described above, reflow processing may require large amounts of heat, which may cause substrate 180 to warp. Thus, another mechanism (described below) for securing portions of substrate 180 during reflow may assist in preventing warpage.

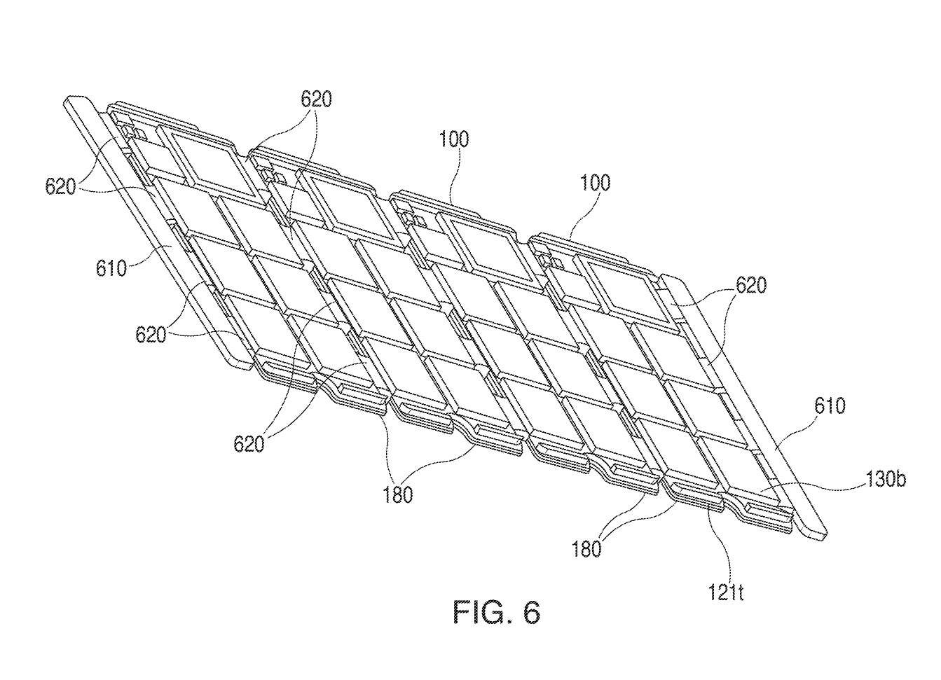

When boards are manufactured, they are typically assembled and processed in batches (e.g., to save time). FIG. 6 shows a perspective view of a batch of board substrates, in accordance with at least one embodiment. A plurality of substrates 180 may be held together in a strip-like fashion to form batch 600. Substrates 180 may be held together by a plurality of tabs 620. Each tab 620 may be coupled to and extend between two columns 610, and may be inserted through a corresponding portion of each substrate 180. For example, each tab 620 may be inserted through an opening in one of the layers of each substrates 180 that may be cutout or formed to allow a tab 620 to pass through. Each substrate 180 may be separated from one another by a particular distance so that portions of each tab 620 may appear between a column 610 and a substrate 180, and between one substrate 180 and another substrate 180.

Batch 600 is shown to include four boards 100 and four tabs 620 that hold the four boards 100 together. It should be appreciated that, although FIG. 6 shows batch 600 including exactly four boards 100 and four tabs 620, batch 600 can instead include any other number of boards 100 and tabs 620 (e.g., 1, 2, 3, etc.). Further, it should be appreciated that, although FIG. 6 shows batch 600 including boards 100 that appear to be completely manufactured, batch 600 can be configured to only include substrates 180 that have not yet undergone one or more of solder pasting, placement of any components thereon, reflow processing, and/or underfill processing.

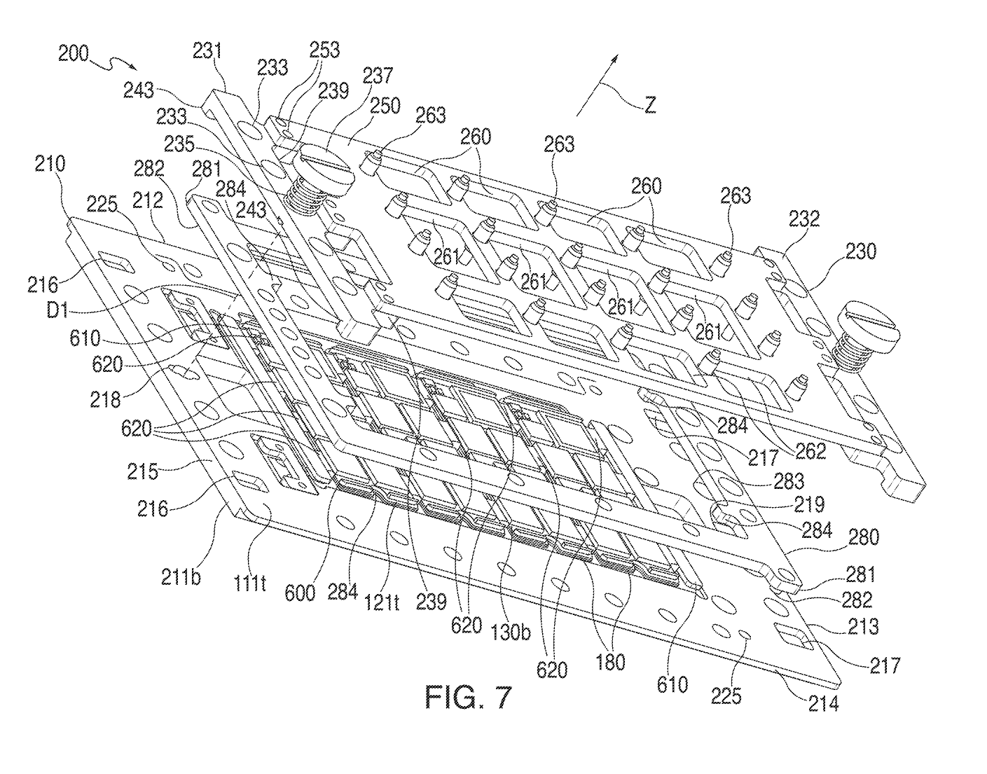

FIG. 7 shows a partially exploded view of a board fixture apparatus, in accordance with at least one embodiment. As described above, mechanisms for securing substrate 180 during solder pasting and reflow processing may assist in preventing warpage. Board fixture apparatus 200 may provide certain mechanical members for securing substrate 180 during these stage of manufacture.

As shown in FIG. 7, batch 600 may rest on board fixture apparatus 200 such that top surface 121t of each substrate 180 may contact a base unit 210 of board fixture apparatus 200. That is, bottom surface 130b of each substrate 180 may be facing away from base unit 210 in a direction Z. In addition to base unit 210, board fixture apparatus 200 may include a magnetic clamp 280 and a pin clamp 230.

Batch 600 may rest on base unit 210, and magnetic clamp 280 may clamp (or fix) batch 600 onto base unit 210 (e.g., when magnetic clamp 280 is properly aligned with base unit 210). For example, magnetic clamp 280 may hold portions of each substrate 180 of batch 600 in place prior to solder pasting. In this manner, substrates 180 of batch 600 may be kept flat and free of warpage during solder pasting.

Pin clamp 230 may also clamp (or fix) batch 600 onto base unit 210. For example, after solder pasting is complete, pin clamp 230 may clamp to base unit 210 and may apply pressure to tabs 620 to flatten each substrate 180 of batch 600 in place prior to reflow. In this manner, substrates 180 of batch 600 may be held substantially flat during reflow processing.

Base unit 210 may be constructed of one or more suitable types of metal that may be magnetic, and may be sized to accommodate one or more substrates 180 of batch 600. Base unit 210 may include a bottom surface 211b and a top surface 211t upon which substrates 180 may rest. Base unit 210 may also include upper edge 212, right edge 213, lower edge 214, and left edge 215.

Base unit 210 may include a plurality of recesses 216 for insertion of corresponding portions of pin clamp 230 (described later). Base unit 210 may include a first set of recesses 216 adjacent to left edge 215, and another set of recesses 216 adjacent right edge 213.

Base unit 210 may also include a plurality of screw holes each for securing a corresponding portion of pin clamp 230 (described later). Base unit 210 may include one screw hole 218 adjacent left edge 215, and another screw hole 218 adjacent right edge 213.

Additionally, base unit 210 may also include a plurality of holes 220 that may allow heat to dissipate from base unit 210 during solder pasting and reflow processing, which may assist in minimizing warpage of substrates 180.

Magnetic clamp 280 may be configured to magnetically attract to base unit 210 when positioned near or on base unit 210. Magnetic clamp 280 may include a window opening 283 that may provide at least partial access to substrates 180 of batch 600 when magnetic clamp 280 is positioned onto base unit 210. Magnetic clamp 280 may include extensions 281 each having a corresponding protrusion 282. Each protrusion 282 may be inserted into a respective hole 225 of base unit 210 to further secure magnetic clamp 280 to base unit 210 (e.g., in addition to the magnetic attraction). In addition, magnetic clamp 280 may also include a plurality of inner notches 284 that may press down onto respective portions of columns 610 of batch 600 to secure batch 600 to base unit 210.

Pin clamp 230 may also be constructed of one or more suitable types of metal that may or may not be magnetic. Pin clamp 230 may include a left support member 230, a right support member 232, and a frame 250 that may be coupled therebetween.

Left support member 230 may include a plurality of openings 233 that may assist left support 230 in dissipating heat during reflow processing. Left support member 230 may include a hole 235 for passing a screw 237. When hole 235 of pin clamp 230 is in line with hole 218 of base unit 210 (as shown by dotted line D1), screw 237 may screw through hole 218 to secure pin clamp 230 to base unit 210. Left support member 230 may also include a plurality of legs 243 each for insertion into a corresponding recess 216 of base unit 210 to further fix pin clamp 230 to base unit 210. Left support member 230 may also include a plurality of supports 239 upon which a corresponding plurality of arms 251 of frame 250 may rest. Each support 239 may include a plurality of holes (not shown) for passing screws (also not shown) for screwing left support member 230 to frame 250. Frame 250 may include a corresponding plurality of holes 253 such that when each hole of support 239 is in line with a corresponding hole 253, a screw may screw therethrough to fix left support member 230 to frame 250.

Frame 250 may include a plurality of windows 260, windows 261, and windows 262, each of which may provide access to a respective portion of a substrate 180 of batch 600. These windows 260, 261, and 262 may allow heat to dissipate from batch 600 during reflow processing. Frame 250 may also include a plurality of pins 263, which may be constructed to have any suitable size or shape. Pins 263 may screw into frame 250 such that portions of each pin 263 may extend on both sides of frame 250. The location of each pin 263 may be defined so as to align with a respective portion of a tab 620 of batch 600. In this manner, while pin clamp 230 clamps to base unit 210, each pin 263 may contact and press onto the respective portion of a tab 620. This may provide structural pressure to hold down portions of each substrate 180 during reflow processing.

Right support member 232 may be similar to left support member 230 and may include similar features as those of left support member 230 for coupling right support member 232 to frame 250 and for fixing right support member 232 to base unit 210.

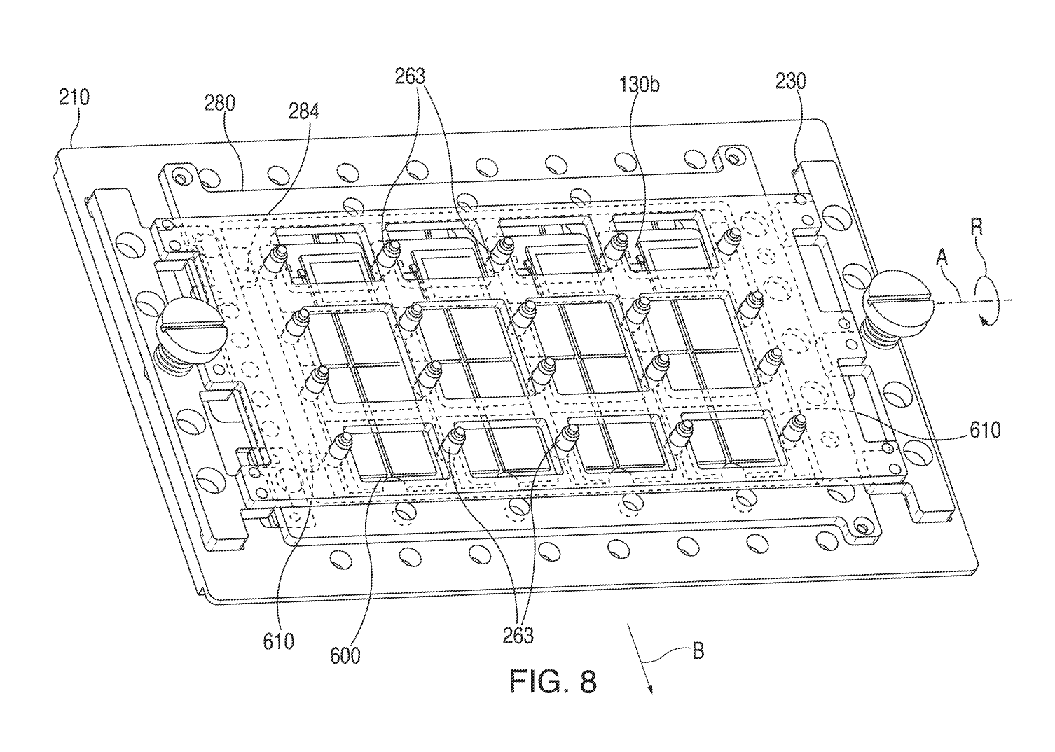

FIG. 8 shows a perspective view of the board fixture apparatus of FIG. 7 fixing the batch of substrates of FIG. 6, in accordance with at least one embodiment. Magnetic clamp 280 may be configured to clamp to base unit 210 and fix batch 600 onto base unit 210 (e.g., via inner notches 284 of magnetic clamp 280 that may press down onto portions of each column 610 of batch 600). Because magnetic clamp 280 may hold batch 600 in place during solder pasting, substrates 180 of batch 600 may experience only minimal warping (e.g., less than the predefined threshold T).

Additionally, pin clamp 230 may also be configured to clamp to base unit 210 and fix batch 600 onto base unit 210 (e.g., via pins 263 that may each press onto a respective portion of a tab 620 of batch 600). Because pin clamp 230 may hold batch 600 in place during reflow, substrates 180 of batch 600 may experience only minimal warping (e.g., less than the predefined threshold T).

As described above, each substrate 180 may rest on base unit 210 such that its corresponding bottom surface 130b may be facing away from base unit 210. Batch 600 may be oriented in this manner based on differences in weights between components mounted on top surface 121t and components mounted on bottom surface 130b. For example, it may be known that board 100 will typically warp in a particular manner (e.g., bottom surface 130b may bend in the direction Z of FIG. 7). Thus, by fixing batch 600 such that bottom surface 130b of each substrate 180 is facing away from base unit 210, each substrate 180 may be prevented from bending in the direction Z of FIG. 7. In some embodiments, each board 100 may instead rest on base unit 210 such that its top surface 121t may be facing away from base unit 210.

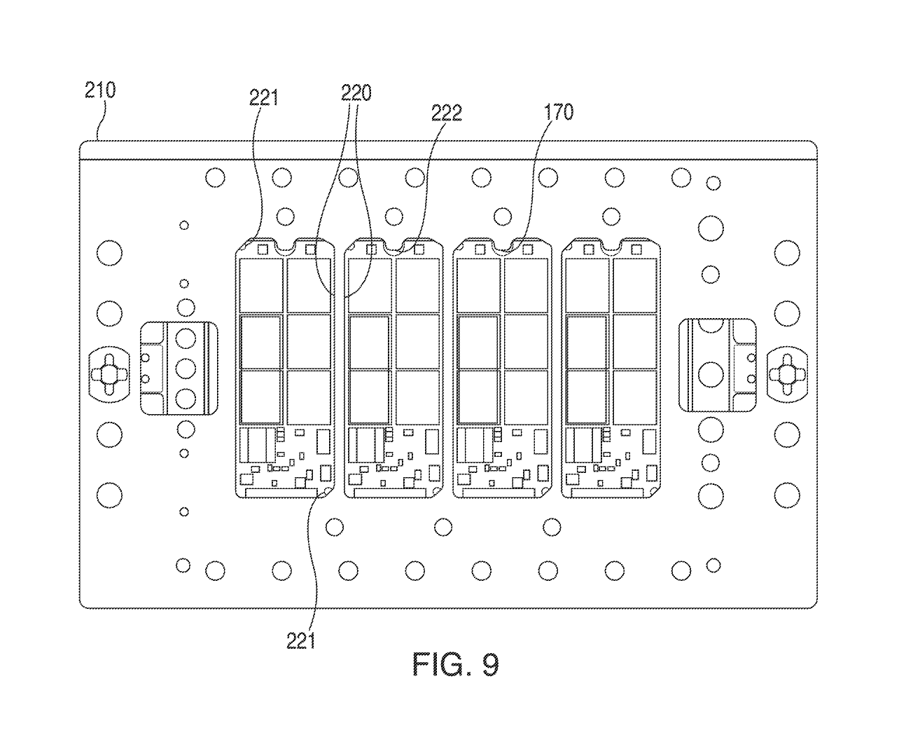

FIG. 9 shows a bottom view of the board fixture apparatus of FIG. 8, taken after rotating board fixture apparatus of FIG. 8 in a direction R, in accordance with at least one embodiment. Base unit 210 may include a plurality of windows 220, each having one or more chamfered edges 221. Portions of each substrate 180 of batch 600 may rest on corresponding edges 221. Each window 220 may include a notch 222 that may fit into a respective cutout 170 of a substrate 180. Notch 222 may serve as an alignment aid for situating each substrate 180 of batch 600 onto base unit 210.

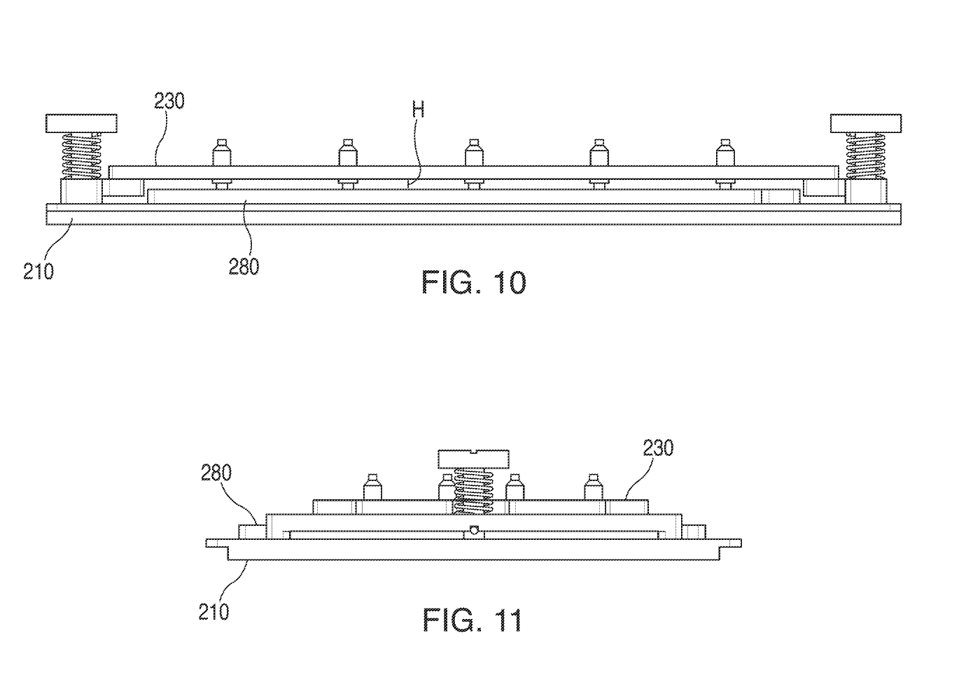

FIG. 10 shows a side view of the board fixture apparatus of FIG. 8, taken along a line B of FIG. 8, in accordance with at least one embodiment. As shown in FIG. 10, each of magnetic clamp 280 and pin clamp 230 may clamp onto respective portions of base unit 210. Cover unit 210 may clamp onto base unit 210 without contacting any portion of magnetic clamp 280. Separation H between magnetic clamp 280 and pin clamp 230 may further allow heat to dissipate when batch 600 is undergoing reflow processing.

FIG. 11 shows another side view of the board fixture apparatus of FIG. 8, taken along a line A of FIG. 8, in accordance with at least one embodiment. As shown in FIG. 11, each of magnetic clamp 280 and pin clamp 230 may clamp onto respective portions of base unit 210 to fix batch 600 onto base unit 210.

Because both sides of substrates 180 of batch 600 may require solder pasting and reflow processing, the same board fixture apparatus 200 may be used regardless of which way substrates 180 may be facing when residing on base unit 210. In some embodiments, after a first side of substrates 180 (e.g., bottom surfaces 130b) undergo solder pasting and reflow processing, batch 600 may be flipped and secured using board fixture apparatus 200 so that a second side of substrates 180 (e.g., top surfaces 121t) may undergo similar processing. In other embodiments, the second side of substrates 180 may be processed while being fixed in a different board fixture apparatus that may be similar to board fixture apparatus 200.

After substrates 180 of batch 600 undergo the necessary reflow processing, substrates 180 may undergo underfill processing. Underfill processing involves solidifying solder that may be at least partially liquefied by the reflow processing. Underfill processing may also involve applying underfill material to the electrical contacts of the components mounted to a substrate. As described above, underfill processing may require the use of heat, which may cause a substrate to warp. However, because underfill may require a different amount of heat and may subject a substrate to different physical conditions, a board fixture apparatus different from board fixture apparatus 200 may be employed.

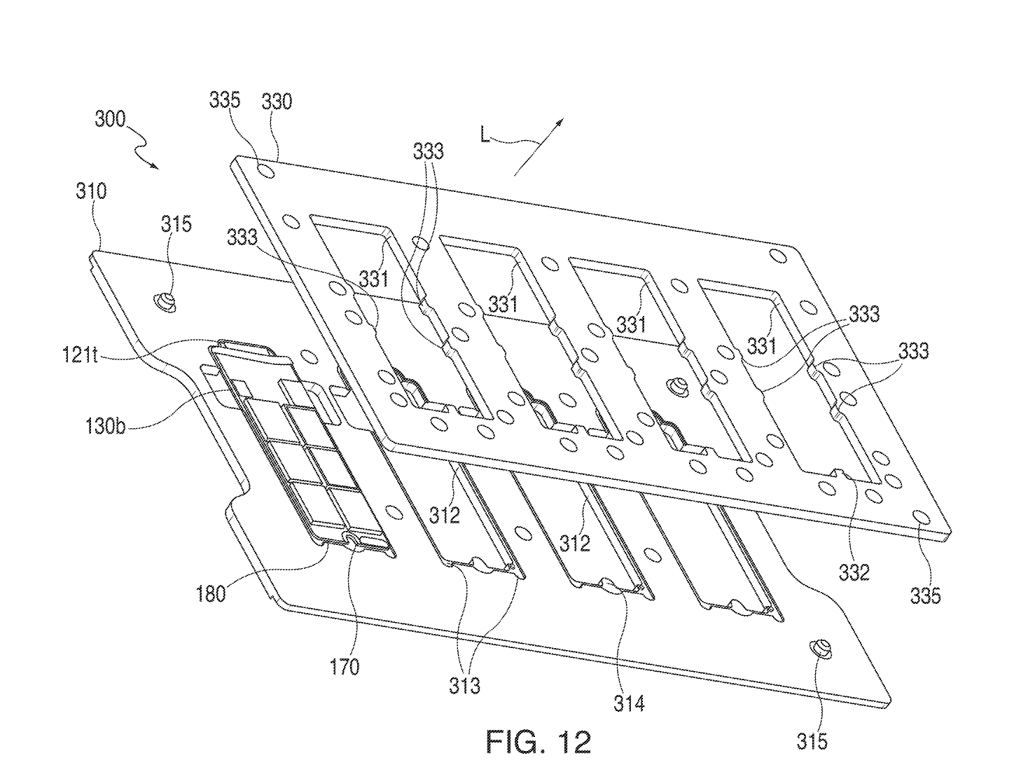

FIG. 12 shows a partially exploded view of another board fixture apparatus, in accordance with at least one embodiment. As shown in FIG. 12, substrates 180 may not couple together (as in batch 600), but may instead be separate from one another. Each substrate 180 may rest on board fixture apparatus 300 such that the bottom surface 130b of each substrate 180 may contact a base part 310. That is, top surface 121t of each substrate 180 may be facing away from base part 310 in the direction L. In addition to base part 310, board fixture apparatus 300 may also include a cover part 330. Cover part 330 may press onto or fix each substrate 180 onto base part 310 (e.g., when cover part 330 is properly aligned with base part 310). In this manner, portions of substrate 180 may be held flat in place during underfill processing, which may assist in preventing warpage. In some embodiments, substrate 180 may experience some warpage after undergoing reflow processing (e.g., while being fixed in board fixture apparatus 200). In these embodiments, board fixture apparatus 300 may assist in reversing any such warpage by pressing each substrate 180 flat using cover part 330 and base part 310.

Base part 310 may be constructed of one or more suitable types of metal, and may accommodate one or more substrates 180 (e.g., that may have undergone solder pasting, component placement, and reflow processing). Base part 310 may include a bottom surface 311b and a top surface 311t upon which substrates may rest. Base part 310 may also include upper edge 320 and lower edge 321.

Base part 310 may include a plurality of windows 312 that may each include a plurality of supports 313 upon which a corresponding substrate 180 may rest. Each window 312 may include a notch 314 that may fit into a respective cutout 170 of substrate 180. Notch 314 may serve as an alignment aid for situating each substrate 180 onto base part 310. Base part 310 may also include a plurality of protrusions 315 that may each be configured and sized to press fit into a corresponding hole 335 of cover part 330 to fix cover part 330 to base part 310.

Cover part 330 may also be constructed of one or more suitable types of metal and may be smaller in size than base part 310. Cover part 330 may include a plurality of windows 331 that may each provide access to a corresponding substrate 180 when cover part 330 fixes to base part 310. Each window 331 may include a notch 332 that may function similar to notch 314 of base part 310. Each window 331 may also include a plurality of protrusions 333 that may each press onto respective portions of a substrate 180 that may be reside between that window 331 and a corresponding window 312 of base part 310.

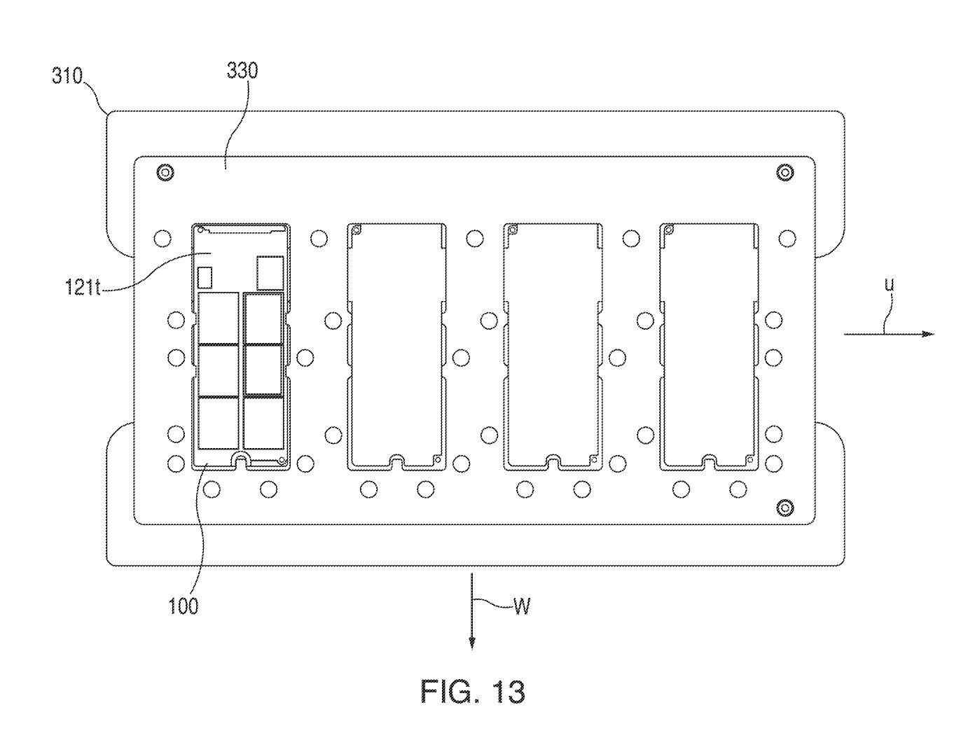

FIG. 13 shows a top view of the board fixture apparatus of FIG. 12, in accordance with at least one embodiment. Cover part 330 may press onto each substrate 180 that may rest on base part 310. In particular, certain protrusions 333 of cover part 330 may press down onto respective portions of each substrate 180.

As described above, each substrate 180 may rest on base part 310 such that its top surface 121t may be facing away from base part 310. Substrate 180 may be oriented in this manner based on differences in weight between components mounted on top surface 121t and components mounted on bottom surface 130b. For example, it may be known that substrate 180 will typically warp in a particular manner (e.g., top surface 121t may bend toward the direction L of FIG. 12). Thus, by fixing substrate 180 such that top surface 121t is facing away from base part 310, each substrate 180 may be prevented from bending in the direction L of FIG. 12. In some embodiments, each substrate 180 may instead rest on base part 310 such that its bottom surface 130b may be facing away from base part 310.

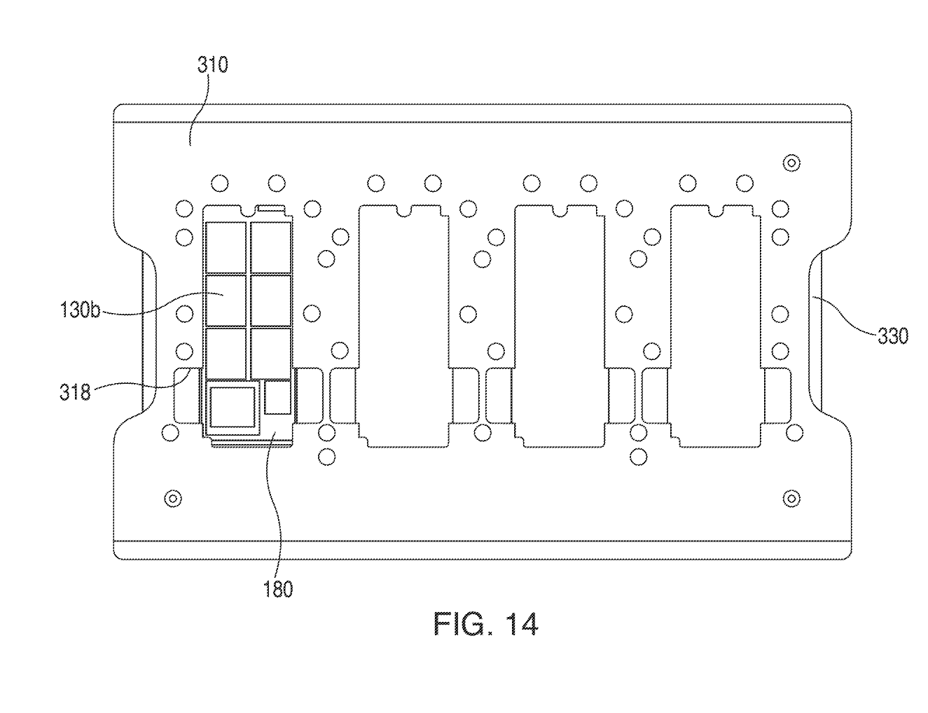

FIG. 14 shows a bottom view of the board fixture apparatus of FIG. 12, in accordance with at least one embodiment. Each window 312 of base part 310 may include a plurality of cutouts 318. As shown in FIG. 14, portions of bottom surface 130b of each substrate 180 may rest on supports 313 and notch 314 of a corresponding window 312.

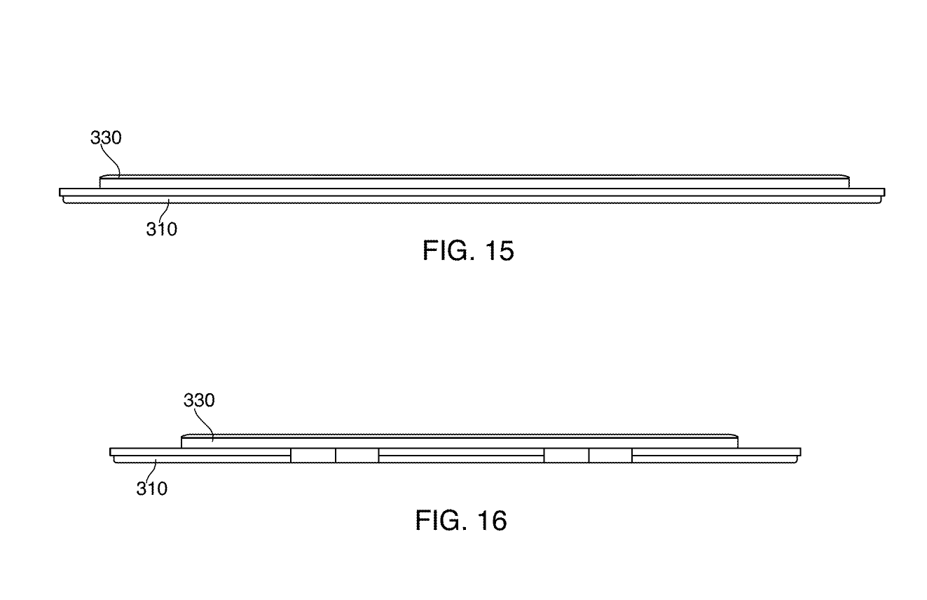

FIG. 15 shows a side view of the board fixture apparatus of FIG. 12, taken along a line W of FIG. 13, in accordance with at least one embodiment. Further, FIG. 16 shows another side view of the board fixture apparatus of FIG. 12, taken along a line U of FIG. 13, in accordance with at least one embodiment. As shown in each of FIGS. 15 and 16, base part 310 and cover part 330 may press onto each other to fix one or more substrates in place (e.g., during underfill processing).

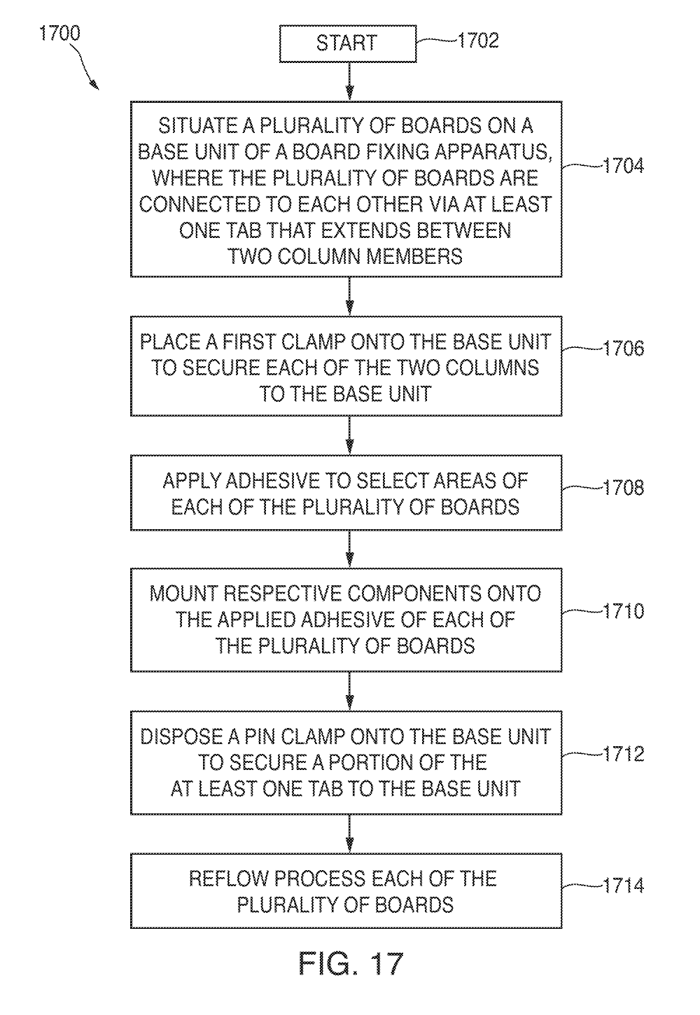

FIG. 17 shows an illustrative process for fixing a plurality of boards prior to and during reflow processing, in accordance with at least one embodiment. Process 1700 may begin at step 1702.

At step 1704, the process may include situating a plurality of boards on a base unit of a board fixing apparatus. The plurality of boards may be connected to each other via at least one tab that extends between two column members. For example, the process may include situating batch 600 onto base unit 210 of board fixing apparatus 200. Batch 600 may include columns 610 and tabs 620 as described above and substrates 180 may be oriented such that bottom surfaces 130b of the substrates 180 may face in the direction Z of FIG. 7.

At step 1706, the process may include placing a first clamp onto the base unit to secure each of the two columns to the base unit. For example, the process may include placing magnetic clamp 280 onto base unit 210 to secure each of columns 610 of batch 600 onto base unit 210.

At step 1708, the process may include applying adhesive to select areas of each of the plurality of boards. For example, the process may include applying solder paste to electrical contacts on bottom surface 130b of each substrate 180 of batch 600.

At step 1710, the process may include mounting respective components onto the applied adhesive of each of the plurality of boards. For example, the process may include placing respective NAND chips 151-156 and circuit components 159 onto the applied solder paste of each substrate 180 of batch 600. In this manner, these components may be physically and electrically coupled to a corresponding bottom surface 130b.

At step 1712, the process may include disposing a pin clamp onto the base unit to secure a portion of the at least one tab to the base unit. For example, the process may include disposing pin clamp 230 onto base unit 210 to secure respective portions of tabs 620 to base unit 210. In this manner, portions of each substrate 180, that may be held by tabs 620, may flatten in place.

At step 1714, the process may include reflow processing each of the plurality of boards. For example, the process may include reflow processing batch 600 while it resides in board fixture apparatus 200.

In some embodiments, after bottom surfaces 130b of substrates 180 have undergone solder pasting and reflow processing, the process may include flipping batch 600 over such that substrates 180 may rest on base unit 210 with top surfaces 121t facing in the direction Z of FIG. 7. Steps 1702-1714 may then be repeated using board fixture apparatus 200. In some embodiments, steps 1702-1714 may be repeated using a different board fixture apparatus.

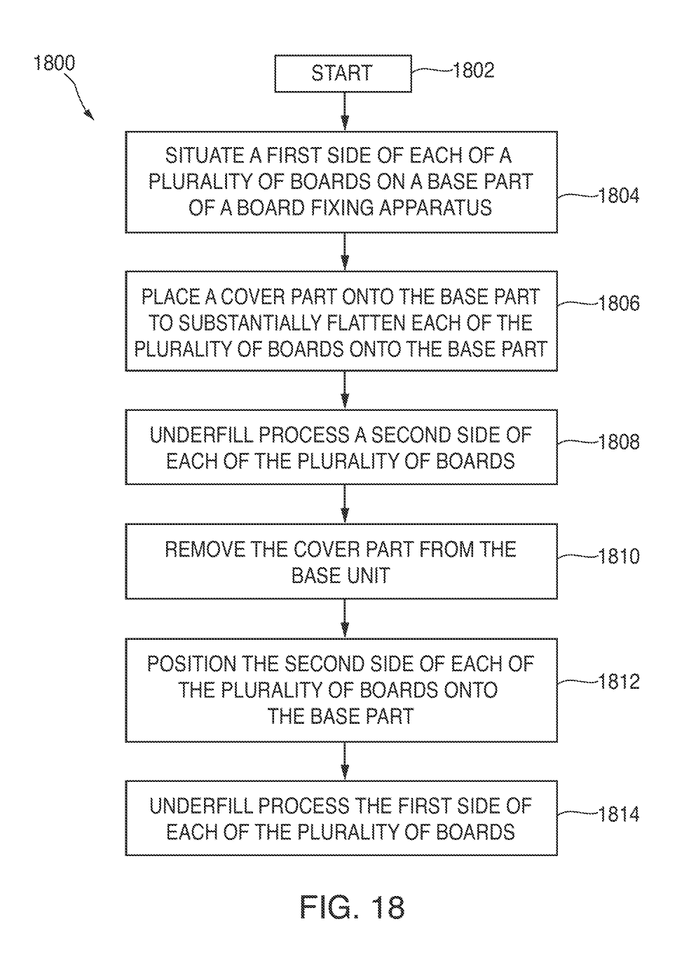

FIG. 18 shows an illustrative process for fixing a plurality of boards for underfill processing, in accordance with at least one embodiment. Process 1800 may begin at step 1802 and may be performed at some time after step 1712 of process 1700.

At step 1804, the process may include situating a first side of each of a plurality of boards on a base part of a board fixing apparatus. For example, the process may include situating individual substrates 180 onto respective regions of base part 310 of board fixing apparatus 300.

At step 1806, the process may include placing a cover part onto the base part to substantially flatten each of the plurality of boards onto the base part. For example, the process may include placing cover part 330 onto base part 310 to substantially flatten each of substrates 180 onto base part 310. In some embodiments, each substrate 180 may be characterized with some warpage after reflow processing (as described above). Thus, notches 333 of each window 331 of cover part 330 may apply pressure to portions of a corresponding substrate 180 when cover part 330 secures to base part 310. That is, one or more portions of top surface 121t of each substrate 180 may tend to bend toward the direction L of FIG. 12. When cover part 330 secures to base part 310, notches 333 may force press onto these one or more portions of the top surfaces 121t to flatten the substrates 180, and thus compensate for any warpage of the substrates 180.

At step 1808, the process may include underfill processing a second side of each of the plurality of boards.

At step 1810, the process may include removing the cover part from the base part. For example, the process may include removing cover part 330 from base part 310.

At step 1812, the process may include positioning the second side of each of the plurality of boards onto the base part. For example, the process may include positioning each substrate 180 such that it resides on base part 310 with its bottom surface 130b facing in the direction L of FIG. 12. At this point, when cover part 330 secures to base part 310, notches 333 may no longer apply any pressure on bottom surfaces 130b of substrates 180, since the substrates 180 may already be sufficiently flat.

At step 1814, the process may include underfill processing the first side of each of the plurality of boards.

One or more of steps of each of processes 1700 and 1800 may be performed by automated machinery in a controlled environment. It is understood that some steps of each of processes 1700 and 1800 may be deleted and additional steps may be added without departing from the spirit of the invention. It should also be appreciated that, although each of processes 1700 and 1800 may have been described for manufacturing a plurality of boards, each of processes 1700 and 1800 may also be employed to manufacture a single board. In these cases, for example, board fixture apparatuses 200, 300, and/or derivations thereof may be employed.

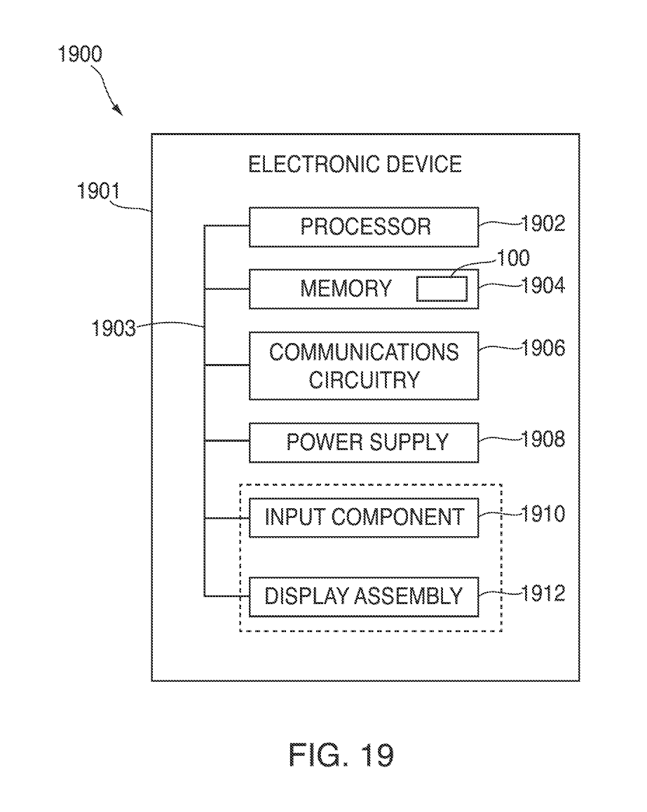

FIG. 19 is a schematic view of an illustrative electronic device including the board of FIG. 1, in accordance with at least one embodiment. Electronic device 1900 may be any portable, mobile, or hand-held electronic device configured to present visible information on a display assembly wherever the user travels. Alternatively, electronic device 1900 may not be portable at all, but may instead be generally stationary. Electronic device 1900 can include, but is not limited to, a music player, video player, still image player, game player, other media player, music recorder, movie or video camera or recorder, still camera, other media recorder, radio, medical equipment, domestic appliance, transportation vehicle instrument, musical instrument, calculator, cellular telephone, other wireless communication device, personal digital assistant, remote control, pager, computer (e.g., desktop, laptop, tablet, server, etc.), monitor, television, stereo equipment, set up box, set-top box, boom box, modem, router, keyboard, mouse, speaker, printer, and combinations thereof.

Electronic device 1900 may include memory 1904, which may include one or more boards 100 described above. Each board 100 may be substantially flat (e.g., having minimal warpage less than the threshold degree of warpage T) and may fit within the confines of electronic device 1900 during and after installation thereof.

In some embodiments, electronic device 1900 may perform a single function (e.g., a device dedicated to displaying image content) and, in other embodiments, electronic device 1900 may perform multiple functions (e.g., a device that displays image content, plays music, and receives and transmits telephone calls).

Electronic device 1900 may include a housing 1901, a processor or control circuitry 1902, communications circuitry 1906, power supply 1908, input component 1910, and display assembly 1912. Electronic device 1900 may also include a bus 1903 that may provide a data transfer path for transferring data and/or power, to, from, or between various other components of device 1900. In some embodiments, one or more components of electronic device 1900 may be combined or omitted. Moreover, electronic device 1900 may include other components not combined or included in FIG. 19. For the sake of simplicity, only one of each of the components is shown in FIG. 19.

In addition to one or more boards 100, Memory 1904 may also include one or more storage mediums, including for example, a hard-drive, flash memory, permanent memory such as read-only memory (“ROM”), semi-permanent memory such as random access memory (“RAM”), any other suitable type of storage component, or any combination thereof. Memory 1904 may include cache memory, which may be one or more different types of memory used for temporarily storing data for electronic device applications. Memory 1904 may store media data (e.g., music, image, and video files), software (e.g., for implementing functions on device 1900), firmware, preference information (e.g., media playback preferences), lifestyle information (e.g., food preferences), exercise information (e.g., information obtained by exercise monitoring equipment), transaction information (e.g., information such as credit card information), wireless connection information (e.g., information that may enable device 1900 to establish a wireless connection), subscription information (e.g., information that keeps track of podcasts or television shows or other media a user subscribes to), contact information (e.g., telephone numbers and e-mail addresses), calendar information, any other suitable data, or any combination thereof.

Communications circuitry 1906 may be provided to allow device 1900 to communicate with one or more other electronic devices or servers using any suitable communications protocol. For example, communications circuitry 1906 may support Wi-Fi™ (e.g., an 802.11 protocol), Ethernet, Bluetooth™, high frequency systems (e.g., 600 MHz, 2.4 GHz, and 5.6 GHz communication systems), infrared, transmission control protocol/internet protocol (“TCP/IP”) (e.g., any of the protocols used in each of the TCP/IP layers), hypertext transfer protocol (“HTTP”), BitTorrent™, file transfer protocol (“FTP”), real-time transport protocol (“RTP”), real-time streaming protocol (“RTSP”), secure shell protocol (“SSH”), any other communications protocol, or any combination thereof. Communications circuitry 1906 may also include circuitry that can enable device 1900 to be electrically coupled to another device (e.g., a computer or an accessory device) and communicate with that other device, either wirelessly or via a wired connection.

Power supply 1908 may provide power to one or more of the components of device 1900. In some embodiments, power supply 1908 can be coupled to a power grid (e.g., when device 1900 is not a portable device, such as a desktop computer). In some embodiments, power supply 1908 can include one or more batteries for providing power (e.g., when device 1900 is a portable device, such as a cellular telephone). As another example, power supply 1908 can be configured to generate power from a natural source (e.g., solar power using one or more solar cells).

One or more input components 1910 may be provided to permit a user to interact or interface with device 1900. For example, input component 1910 can take a variety of forms, including, but not limited to, a track pad, dial, click wheel, scroll wheel, touch screen, one or more buttons (e.g., a keyboard), mouse, joy stick, track ball, and combinations thereof. For example, input component 1910 may include a multi-touch screen. Each input component 1910 can be configured to provide one or more dedicated control functions for making selections or issuing commands associated with operating device 1900.

Electronic device 1900 may also include one or more output components that may present information (e.g., textual, graphical, audible, and/or tactile information) to a user of device 1900. An output component of electronic device 1900 may take various forms, including, but not limited, to audio speakers, headphones, audio line-outs, visual displays, antennas, infrared ports, rumblers, vibrators, or combinations thereof.

For example, electronic device 1900 may include display assembly 1912 as an output component. Display 1912 may include any suitable type of display or interface for presenting visible information to a user of device 1900. In some embodiments, display 1912 may include a display embedded in device 1900 or coupled to device 1900 (e.g., a removable display). Display 1912 may include, for example, a liquid crystal display (“LCD”), a light emitting diode (“LED”) display, an organic light-emitting diode (“OLED”) display, a surface-conduction electron-emitter display (“SED”), a carbon nanotube display, a nanocrystal display, any other suitable type of display, or combination thereof. Alternatively, display 1912 can include a movable display or a projecting system for providing a display of content on a surface remote from electronic device 1900, such as, for example, a video projector, a head-up display, or a three-dimensional (e.g., holographic) display. As another example, display 1912 may include a digital or mechanical viewfinder. In some embodiments, display 1912 may include a viewfinder of the type found in compact digital cameras, reflex cameras, or any other suitable still or video camera.

It should be noted that one or more input components and one or more output components may sometimes be referred to collectively as an I/O interface (e.g., input component 1910 and display 1912 as I/O interface 1911). It should also be noted that input component 1910 and display 1912 may sometimes be a single I/O component, such as a touch screen that may receive input information through a user's touch of a display screen and that may also provide visual information to a user via that same display screen.

Processor 1902 of device 1900 may control the operation of many functions and other circuitry provided by device 1900. For example, processor 1902 may receive input signals from input component 1910 and/or drive output signals to display assembly 1912. Processor 1902 may load a user interface program (e.g., a program stored in memory 1904 or another device or server) to determine how instructions or data received via an input component 1910 may manipulate the way in which information is provided to the user via an output component (e.g., display 1912). For example, processor 1902 may control the viewing angle of the visible information presented to the user by display 1912 or may otherwise instruct display 1912 to alter the viewing angle.

Electronic device 1900 may also be provided with a housing 1901 that may at least partially enclose one or more of the components of device 1900 for protecting them from debris and other degrading forces external to device 1900. In some embodiments, one or more of the components may be provided within its own housing (e.g., input component 1910 may be an independent keyboard or mouse within its own housing that may wirelessly or through a wire communicate with processor 1902, which may be provided within its own housing).

The described embodiments of the invention are presented for the purpose of illustration and not of limitation.

What is claimed is:

1. A board having a substantially flat surface throughout an entirety of the board, the board comprising:
a substrate having at least a top layer and a bottom layer, wherein at least one of the top layer and the bottom layer comprises a copper flooded region; and
a plurality of components comprising:
a first set of components mounted on the top layer; and
a second set of components mounted on the bottom layer, wherein at least one of the copper flooded region, the first set of components, and the second set of components is selectively positioned on the board to prevent the board from warping beyond a predefined threshold degree of warpage.

2. The board assembly of claim 1, wherein the board comprises a solid state device (SSD) board.

3. The board assembly of claim 1, wherein the first set of components comprises a first plurality of NAND chips.

4. The board assembly of claim 3, wherein the second set of components comprises a second plurality of NAND chips and a controller.

5. The board assembly of claim 4, wherein the first plurality of NAND chips are selectively positioned with respect to the second plurality of NAND chips to prevent the substrate from warping beyond the predefined threshold degree of warpage.

6. The board assembly of claim 4, wherein the controller is selectively positioned with respect to at least one of the first plurality of NAND chips and the second plurality of NAND chips to prevent the substrate from warping beyond the predefined threshold degree of warpage.

7. The board assembly of claim 1, wherein the copper flooded region is the only region of the board that comprises copper flooding.

8. The board assembly of claim 1, wherein the predefined threshold degree of warpage comprises an angle.

9. A board fixing apparatus for securing a plurality of boards each coupled via at least one tab that extends between two column members, the apparatus comprising:
a base unit comprising a plurality of regions, each region configured to hold a respective board of the plurality of boards;
a first clamp comprising at least two notches, each notch configured to fix a respective column member of the two column members to the base unit to secure the plurality of boards to the base unit; and
a second clamp comprising at least one pin configured to press onto a portion of the at least one tab to further secure the plurality of boards to the base unit.

10. The board fixing apparatus of claim 9, wherein at least one of the first clamp and the second clamp secures the plurality of boards to the base unit to prevent each of the plurality of boards from warping beyond a predefined threshold degree of warpage.

11. The board fixing apparatus of claim 9, wherein the base unit is composed of magnetic metal.

12. The board fixing apparatus of claim 11, wherein the first clamp is composed of magnetic metal and is configured to magnetically attract to the base unit.

13. The board fixing apparatus of claim 9, wherein the first clamp comprises a window that:
includes the at least two notches; and
that provides at least partial access to the plurality of boards when the first clamp is secured to the base unit.

14. The board fixing apparatus of claim 9, wherein the second clamp comprises at least one support member for coupling to each of the base unit and the first clamp.

15. The board fixing apparatus of claim 9, wherein the second clamp comprises a frame having a plurality of windows that each provides at least partial access to a respective board of the plurality of boards when the second clamp is secured to the based unit.

16. The board fixing apparatus of claim 15, wherein the at least one pin is situated between two windows of the plurality of windows.

17. A board fixing apparatus for securing a plurality of boards, the apparatus comprising:
a base part comprising a plurality of regions, each region configured to hold a respective one of the plurality of boards; and
a cover part comprising a plurality of notches, each notch configured to fix a portion of a respective one of the plurality of boards to the base part.

18. The board fixing apparatus of claim 17, wherein each of the plurality of notches are configured to secure the respective one of the plurality of boards to the base part to prevent each of the plurality of boards from warping beyond a predefined threshold degree of warpage.

19. The board fixing apparatus of claim 17, wherein each of the plurality of notches is configured to apply pressure to the respective one of the plurality of boards onto the base part to correct warpage of that respective board.

20. The board fixing apparatus of claim 17, wherein each of the base part and the cover part is composed of metal.

21. The board fixing apparatus of claim 17, wherein the base part comprises at least one protrusion, and wherein cover part comprises at least one hole configured to couple to the at least one protrusion to secure the cover part to the base part.

22. The board fixing apparatus of claim 17, wherein the cover part comprises a plurality of windows that each provide at least partial access to a respective board of the plurality of boards when the cover part is secured to the based part.

23. The board fixing apparatus of claim 22, wherein each of the plurality of windows comprises at least one of the plurality of notches.

24. A method for minimizing warpage of a board during manufacture, the method comprising:
situating a plurality of boards on a base unit of a board fixing apparatus, wherein the plurality of boards are connected to one another via at least one tab that extends between two column members;
placing a first clamp of the board fixing apparatus onto the base unit to secure each of the two column members to the base unit;
applying adhesive to select areas of each of the plurality of boards;
mounting respective components onto the applied adhesive of each of the plurality of boards;
disposing a pin clamp of the board fixing apparatus onto the base unit to secure a portion of the at least one tab to the base unit; and
reflow processing each of the plurality of boards.

25. The method of claim 24, wherein the situating comprises situating each of the plurality of boards on a respective region of the base unit.

26. The method of claim 24, wherein the placing comprises placing at least one notch of the first clamp onto a respective one of the two column members.

27. The method of claim 24, wherein the applying comprises applying solder to electrical contacts on each of the plurality of boards.

28. The method of claim 27, wherein the mounting comprises mounting the respective components onto the applied solder.

29. The method of claim 24, wherein the disposing comprises disposing at least one pin of the pin clamp onto the portion of the at least one tab to prevent at least one board of the plurality of boards from warping beyond a predefined threshold of warpage.

30. A method for minimizing warpage of a board during manufacture, the method comprising:
situating a first side of each of a plurality of boards on a base part of a board fixing apparatus;
placing a cover part of the board fixing apparatus onto the base part to substantially flatten each of the plurality of boards onto the base part;
underfill processing a second side of each of the plurality of boards;
removing the cover part from the base unit;
positioning the second side of each of the plurality of boards onto the base part; and
underfill processing the first side of each of the plurality of boards.

31. The method of claim 30, wherein the situating comprises situating the first side of each of the plurality of boards onto a respective region of the base part.

32. The method of claim 30, wherein the placing comprises placing at least one notch of a plurality of notches of the cover part onto a respective portion of the second side of each of the plurality of boards to prevent each of the plurality of boards from warping beyond a predefined threshold of warpage.

33. The method of claim 30, wherein the underfill processing the second side of each of the plurality of boards comprises underfill processing a controller of each of the plurality of boards.
